(19) United States
(12) Patent Application Publication
(10) Pub. No.: US 2025/0335662 A1
(43) Pub. Date: Oct. 30, 2025

(54) ELASTIC COUPLING BETWEEN DIGITAL TWIN AND PHYSICAL ARTIFACT

(71) Applicant: Hewlett Packard Enterprise Development LP, Spring, TX (US)

(72) Inventors: Dejan S. Milojicic, Palo Alto, CA (US); Utz-Uwe Haus, Zurich (CH); Cullen E. Bash, Los Gatos, CA (US)

(21) Appl. No.: 18/651,229

(22) Filed: Apr. 30, 2024

(51) Int. Cl. G06F 30/27

(52) U.S. Cl. CPC G06F 30/27

(57) ABSTRACT

A method includes collecting data of states from a physical artifact at a first frequency using one or more data collection devices, wherein the states describe performance of the physical artifact in real-time, instantiating a first digital representation comprising a digital twin of the physical artifact, wherein the first digital representation mimics the physical artifact and a first state of the states, conducting an analysis to determine whether a first granularity of the collected data is sufficient based upon whether the first state falls within boundaries of operation that are expected for the digital twin, and adjusting a resolution at which the digital twin represents the physical artifact based upon the analysis to determine whether the first granularity of the collected data is sufficient.

### BACKGROUND

A digital twin is a virtual representation or model of a physical artifact, a system, or other asset. The digital twin may mirror the properties, behavior, and interactions of the physical artifact or system that it represents, potentially in real-time. The digital twin may utilize a wide range of data, models, and simulations to monitor and analyze the behavior of the physical artifact or system and predict future outcomes, simulate scenarios, and optimize operations in a virtual environment before implementing changes in the real world. Data from the physical artifact or system is collected (e.g., through the use of sensors), analyzed, and interpreted, and mapped to the virtual model of the digital twin. The digital twin may thus allow a user to understand how the physical artifact or system is performing, as well as allowing the user to predict how the physical artifact or system may perform in the future using the collected data.

### BRIEF DESCRIPTION OF THE DRAWINGS

Aspects of the present disclosure are best understood from the following detailed description when read with the accompanying figures.

FIG. 1 illustrates an example system for processing a digital twin, according to some implementations.

FIG. 2A illustrates an autonomous adjustment of the coupling depth between a digital twin and a physical artifact, according to some implementations.

FIG. 2B illustrates an autonomous adjustment of the coupling frequency between a digital twin and a physical artifact, according to some implementations.

FIG. 2C illustrates an autonomous and simultaneous adjustment of the coupling depth and the coupling frequency between a digital twin and a physical artifact, according to some implementations.

FIG. 2D illustrates factors that influence the autonomous adjustment of the granularity or degree of coupling between a digital twin and a physical artifact, according to some implementations.

FIG. 3 illustrates an example implementation of the use of one or more elasticity triggers to autonomously adjust the granularity or degree of coupling between a digital twin and a physical artifact, according to some implementations.

FIG. 4 illustrates a flowchart for an adjustment process that is used to adjust the granularity or degree of coupling between a digital twin and a physical artifact, according to some implementations.

FIG. 5 illustrates a flowchart for a process performed by a user in response to an error report generated during the adjustment process, according to some implementations.

FIG. 6 illustrates an example method for autonomously adjusting the granularity or degree of coupling between a digital twin and a physical artifact, according to some implementations.

FIG. 7 illustrates an example method for autonomously adjusting the granularity or degree of coupling between a digital twin and a physical artifact, according to some implementations;

Corresponding numerals and symbols in the different figures generally refer to corresponding parts unless otherwise indicated. The figures are drawn to clearly illustrate the relevant aspects of the disclosure and are not necessarily drawn to scale.

### DETAILED DESCRIPTION

The following disclosure provides many different examples for implementing different features. Specific examples of components and arrangements are described below to simplify the present disclosure. These are, of course, merely examples and are not intended to be limiting.

Digital twins are increasingly being used to perform a wide variety of different tasks. For example, they may be used to perform “what-if analysis”, where changes may be made to one or more variables or parameters within the virtual model of the physical artifact or system, and how the changes affect the overall outcome or performance of the physical artifact or system is then observed. In addition, digital twins may be used to perform prediction of larger scales, where forecasts and projections about phenomena or events at higher levels of aggregation or scale can be made. These may include climate modeling, economic modeling, and natural hazard predictions. Digital twins may further be used to test planned configuration changes on the virtual model of the physical artifact or system, in order to observe how the planned configuration changes would affect the overall outcome or performance of the physical artifact or system if the configuration changes were actually made on the physical artifact or system. Digital twins may also be used to test planned extensions on the virtual model of the physical artifact or system, in order to observe how the planned extensions would affect the overall outcome or performance of the physical artifact or system if the extensions were added on the physical artifact or system. These extensions may include additional features, functionalities, or capabilities that can be added to the physical artifact or system to enhance its functionality or capabilities.

Certain implementations of this disclosure provide a self-adaptive solution that can dynamically and autonomously adjust the granularity or degree of coupling for a digital twin as needed (e.g., by adjusting between the collection of more detailed data from multiple layers of subcomponents of the digital twin, and the collection of less detailed or summarized data that may just focus on aggregated information relating to the whole digital twin). The self-adaptive solution enables coupling elasticity between the digital twin and the physical artifact or system, wherein coupling elasticity refers to the ability to dynamically adjust the degree of coupling (e.g., interaction and synchronization) of the digital twin with the physical artifact or system that it represents, based on changing conditions, requirements, or objectives. For example, the self-adaptive solution can adjust and switch between degrees of coupling by adjusting various coupling elasticity variables such as coupling depth between the digital twin and the physical artifact or system, or coupling frequency between the digital twin and the physical artifact or system. The self-adaptive solution can dynamically adjust these variables autonomously based on a combination of the state of the digital twin (in real-time), user input (e.g., through a user-interface (UI) for effective digital twin management), and various policies that define preferences and restrictions under which the digital twin should operate. In addition, one or more of the coupling elasticity variables can be used as an elasticity trigger such that, if the one or more coupling elasticity variables achieves or exceeds a pre-defined condition or state, the self-adaptive solution will dynamically adjust the granularity of coupling the digital twin has with the physical artifact or system that it represents as needed.

Certain implementations of this disclosure may reduce the need for manual intervention in repetitive or routine tasks, allowing users to focus on more strategic and value-added activities. The implementations may also allow for faster detection and reduced response times to critical events due to the reduction in the need for manual intervention. The implementations may allow for automated detection and remediation of anomalies both with and without user supervision. In addition, the implementations may allow for the elimination of false negatives that fail to indicate the presence of an abnormality or error, even when the error is present. Further, the implementations may reduce the occurrences of false positives in which errors may be identified as present, even though they are actually absent. The implementations may also allow for the consistent application of and compliance with policy requirements across both the digital twin and the physical artifact or system. Further, the implementations may enhance the safety of the physical artifact or system by enabling real-time monitoring (e.g., while using a digital twin that tracks physical machinery, or the like). Additionally, the implementations allow digital twins that are equipped with appropriate Verification, Validation, and Uncertainty Quantification analysis capabilities to offer robust safety guarantees in various industrial, manufacturing, and infrastructure settings.

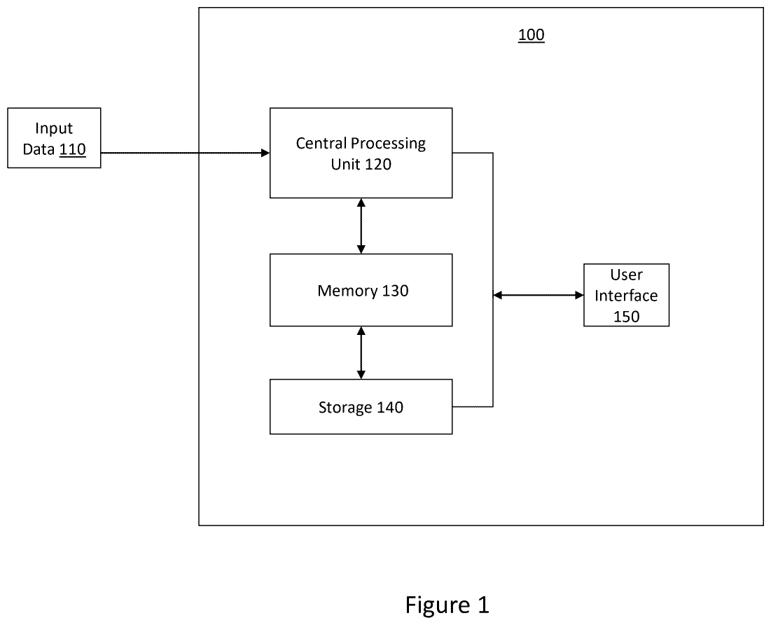

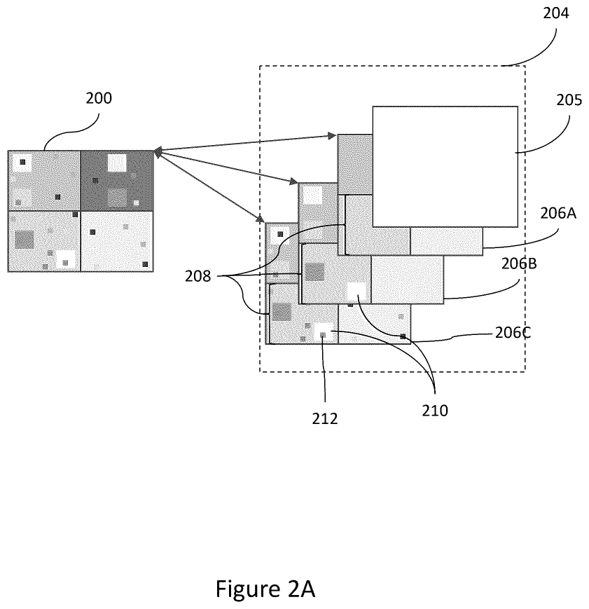

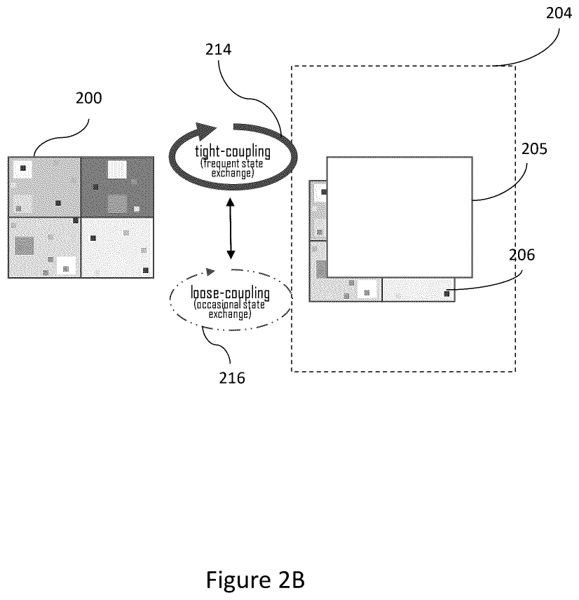

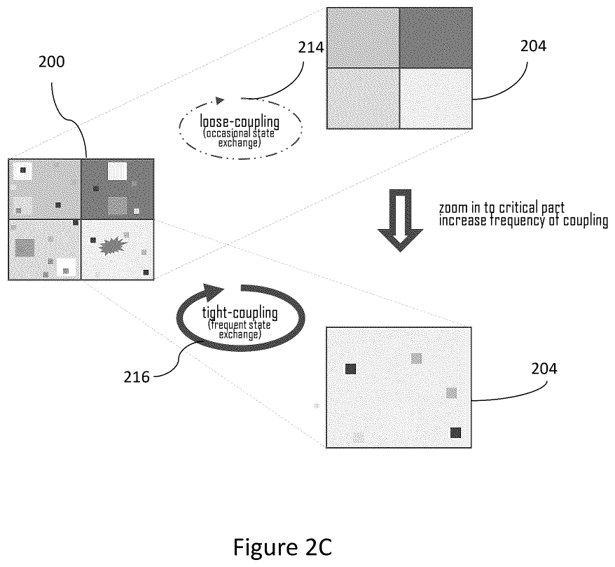

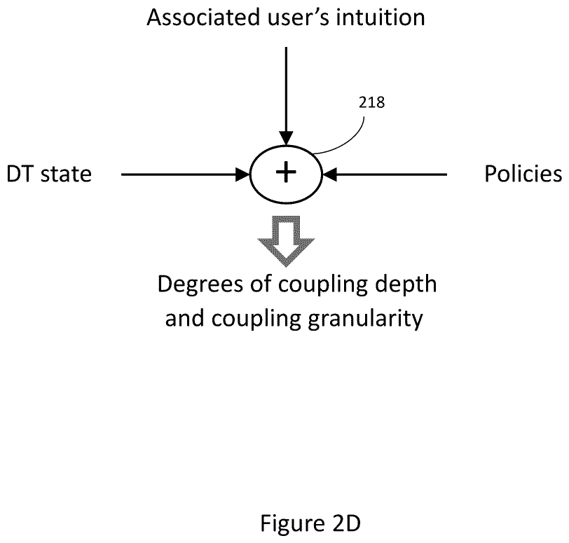

FIG. 1 illustrates an example system 100 for processing a digital twin. The digital twin may utilize a wide range of data, models, and simulations to monitor and analyze the behavior of a physical artifact (e.g., the physical artifact 200 shown subsequently in FIGS. 2A-2D). The digital twin may be utilized to predict future outcomes, simulate scenarios, and optimize operations in a virtual environment before implementing changes to the physical artifact in the real world. The digital twin may be used for a diverse set of physical artifacts, such as machinery, data centers, airplanes, ocean environments, or the like.

In an implementation, the system 100 may provide computational resources, memory resources, storage capacity, input/output interfaces, and network connectivity required to support the functionality and operation of the digital twin. The system 100 may receive input data 110 from sensors and other data collection devices. The input data 110 may include data collected in real-time (e.g., temperature, pressure, energy consumption, quality metrics, or the like) from the physical artifact that is used by the digital twin to mirror the properties, behavior, and interactions of the physical artifact that it represents in real-time.

The system 100 may include a central processing unit (CPU) 120 which is used to process the input data 110 from the physical artifact and transform it into a digital representation of the physical artifact. This representation may include geometric, spatial, temporal, and attribute data that accurately reflects the physical characteristics and behavior of the physical artifact.

The system 100 may include a main memory 130 which may include a non-transitory computer readable medium that stores programming for execution by the CPU 120. The system 100 may also include storage 140, which is used to store, for example, the digital twin software, data files, models, configurations, or the like, that are used for the operation of the digital twin. The storage 140 may include hard disk drives (HDD), solid-state drives (SSD), or the like.

The system may include a user-interface (UI) 150 that serves as the primary means for users to interact with and visualize the digital representation (e.g., the digital twin) of the physical artifact. The user-interface (UI) 150 may be, for example, a graphical user-interface (GUI), a web-based portal, or the like, through which the digital twin is presented to users. The user-interface (UI) 150 can therefore be used to visualize, for example, real-time or historical data collected from the physical artifact using sensors and other data collection devices, simulation results, predicted outcomes, “what-if analysis” outcomes, or the like, in order to allow the user to gain insight into the physical artifact's performance and behavior.

FIGS. 2A-2D illustrate the dynamic and autonomous adjustment of the granularity or degree of coupling for a digital twin 204. FIG. 2A illustrates the dynamic and autonomous adjustment of the granularity or degree of coupling for a digital twin 204 by adjusting the coupling depth between the digital twin 204 and a physical artifact 200. In an implementation, the digital twin 204 may be a virtual representation of the physical artifact 200, and the digital twin 204 may operate on the system 100 that was described previously in FIG. 1. The dynamic and autonomous adjustment of the granularity or degree of coupling for the digital twin 204 is carried out using a self-adaptive solution that runs on the system 100, wherein the system 100 also hosts the digital twin 204.

The self-adaptive solution enables coupling elasticity between the digital twin 204 and the physical artifact 200, wherein coupling elasticity refers to the ability to dynamically adjust the degree of coupling (e.g., interaction and synchronization) of the digital twin 204 with the physical artifact 200 that it represents, based on changing conditions, requirements, or objectives. For example, the self-adaptive solution can adjust and switch between degrees of coupling by adjusting various coupling elasticity variables such as coupling depth between the digital twin 204 and the physical artifact 200, or coupling frequency (described subsequently in FIG. 2B) between the digital twin 204 and the physical artifact 200. The self-adaptive solution can dynamically adjust these coupling elasticity variables autonomously as well as automatically optimize its models, algorithms, or control strategies based on a combination of the state of the digital twin 204 in real-time, user input (e.g., through the user-interface (UI) 150 for effective digital twin management), and various policies that define preferences and restrictions under which the digital twin 204 should operate (e.g., as described subsequently in FIG. 2D).

The adjusting of the coupling elasticity variables may include using refinement strategies that are used to enhance the resolution of the digital twin 204. For example, uniform subdivision may be used to partition the digital twin 204 into equally sized or spaced segments. In another example, non-uniform division may be used to partition the digital twin 204 into segments of varying sizes or spacing, based on certain criteria or properties. Non-uniform division may include partitioning the digital twin 204 into segments based on the frequency distribution of values, partitioning the digital twin 204 based on statistical distribution functions, such as gaussian, exponential, or poisson distributions, or partitioning the digital twin 204 based on geometric characteristics or properties.

In an implementation, the self-adaptive solution can adjust and switch between degrees of coupling by using categorical parameters to determine whether to operate in a continuous mode, discrete state mode, finite automaton mode, or employ a polyhedral approximation of a nonlinear model. Each mode represents a different level or type of coupling between the digital twin 204 and the physical artifact 200. In an implementation, the self-adaptive solution can adjust and switch between degrees of coupling by employing exchangeable or interchangeable modules, each representing a different mode of coupling.

In an implementation, the self-adaptive solution may also be used to autonomously adjust the speed/acceleration of coupling elasticity based on changing conditions, requirements, or objectives. The speed/acceleration of coupling elasticity refers to how fast the self-adaptive solution can dynamically adjust the degree of coupling (e.g., by adjusting coupling depth or coupling frequency) of the digital twin 204 with the physical artifact 200 that it represents. The speed of coupling elasticity may be controlled using the discrete derivative of an observed effect. For example, by discretizing the derivative of the observed effect, it can be calculated and used to control the speed of coupling elasticity. The observed effect may be caused by for example, a recent refinement operation, a coarsening operation, or a moving window approach that is used to find the minimum or maximum of a function within a specified interval.

The digital twin 204 may be a virtual representation of any of a diverse set of physical artifacts, such as machinery, data centers, airplanes, ocean environments, or the like. The digital twin 204 may be generated in the form of a general representation 205 that captures less detailed or summarized data, and instead may focus on aggregated information relating to the whole physical artifact 200. The self-adaptive solution autonomously switches the coupling depth between the digital twin 204 and the physical artifact 200 by switching between the general representation 205 of the physical artifact 200 and more detailed representations 206 of the physical artifact 200, having multiple levels of scale or granularity. For example, the self-adaptive solution may switch the digital twin 204 from a general representation 205 to a detailed representation 206 (e.g., detailed representation 206A, detailed representation 206B, or detailed representation 206C) of the physical artifact 200 depending on a combination of the state of the digital twin 204 in real-time, user input, and various policies that define preferences and restrictions under which the digital twin 204 should operate. As used herein, switching the digital twin 204 may include changing a level of detail or resolution of the representation of the digital twin 204. Each of the detailed representations 206A, 206B, and 206C, may be representations of the physical artifact 200 that have higher levels of detail or resolution than the general representation 205.

In an implementation, the detailed representation 206B may have a higher resolution than the detailed representation 206A, and the detailed representation 206C may have a higher resolution than the detailed representation 206B. Having a higher resolution may include the representation of a greater number of components and sub-components of the physical artifact 200, wherein the physical artifact 200 is broken down or partitioned into smaller and more detailed elements. For example, in an implementation, the detailed representations 206A/206B/206C may include partitions 208, the detailed representations 206B/206C may include sub-partitions 210, and the detailed representation 206C may include additional sub-partitions 212. A digital twin having a higher resolution may include the representation of a greater number of performance parameters of the physical artifact 200, such as accuracy, reliability, precision, or the like. In an implementation, the self-adaptive solution autonomously switches the digital twin 204 from a general representation 205 to a detailed representation 206 (e.g., detailed representation 206A, detailed representation 206B, or detailed representation 206C) of the physical artifact 200. In an implementation, the self-adaptive solution additionally autonomously switches the digital twin 204 from a detailed representation 206 (e.g., detailed representation 206A, detailed representation 206B, or detailed representation 206C) of the physical artifact 200 to a general representation 205 of the physical artifact 200. In an implementation, the self-adaptive solution further autonomously switches the digital twin 204 from a detailed representation 206 (e.g., detailed representation 206A, detailed representation 206B, or detailed representation 206C) of the physical artifact 200 to another detailed representation 206 (e.g., detailed representation 206A, detailed representation 206B, or detailed representation 206C) of the physical artifact 200.

FIG. 2B illustrates the dynamic and autonomous adjustment of the granularity or degree of coupling for a digital twin 204 by adjusting the coupling frequency between the digital twin 204 and a physical artifact 200. As used herein, coupling frequency may include a frequency of interaction and state exchange between the digital twin 204 and the physical artifact 200. The digital twin 204 may operate on the system 100 that was described previously in FIG. 1. The dynamic and autonomous adjustment of the granularity or degree of coupling for the digital twin 204 is carried out using the self-adaptive solution (described previously in FIG. 2A) that runs on the system 100, wherein the system 100 also hosts the digital twin 204.

The self-adaptive solution autonomously switches the coupling frequency between the digital twin 204 and the physical artifact 200 by switching between a tight-coupled configuration 214 and a loose-coupled configuration 216. For example, the self-adaptive solution may switch the digital twin 204 between the tight-coupled configuration 214 and the loose-coupled configuration 216, depending on a combination of the state of the digital twin 204 in real-time, user input, and various policies that define preferences and restrictions under which the digital twin 204 should operate. A degree of integration and synchronization between the digital twin 204 and the physical artifact 200 in the tight-coupled configuration 214 is higher than a degree of integration and synchronization between the digital twin 204 and the physical artifact 200 in the loose-coupled configuration 216. For example, exchange of state information in real-time between the physical artifact 200 and the digital twin 204 in order to update the digital twin's 204 representation of the physical artifact 200 may occur at a higher frequency in the tight-coupled configuration 214 than in the loose-coupled configuration 216.

Autonomously adjusting the granularity or degree of coupling for the digital twin 204 by adjusting the coupling frequency between the digital twin 204 and the physical artifact 200 may have uses in control systems that utilize feedback and feedforward control. For example, in applications such as high-performance computing (HPC), or the like, feedback control can be utilized that involves monitoring the output or performance of a system and using this information to adjust the system's behavior. The frequency of the state exchanged in real-time related to the output or performance of the system can be adjusted autonomously based on changing conditions, requirements, or objectives. In another example, in applications such as weather prediction, or the like, feedforward control can be utilized that anticipates disturbances or changes in a system and proactively adjusts the system's inputs or parameters to minimize the effects. The frequency of state exchange related to the predictive models or estimations that the system makes can be adjusted autonomously based on changing conditions, requirements, or objectives.

FIG. 2C illustrates the dynamic and autonomous adjustment of the granularity or degree of coupling for a digital twin 204 (e.g., in the form of a general representation 205 or a detailed representation 206) by adjusting the coupling depth and/or the coupling frequency between the digital twin 204 and the physical artifact 200. As used herein, coupling depth may include a level of detail or resolution of the representation by the digital twin 204 of the physical artifact 200. The coupling depth and the coupling frequency may be autonomously adjusted at the same time by the self-adaptive solution (e.g., described previously in FIGS. 2A-2B) based on changing conditions, requirements, or objectives.

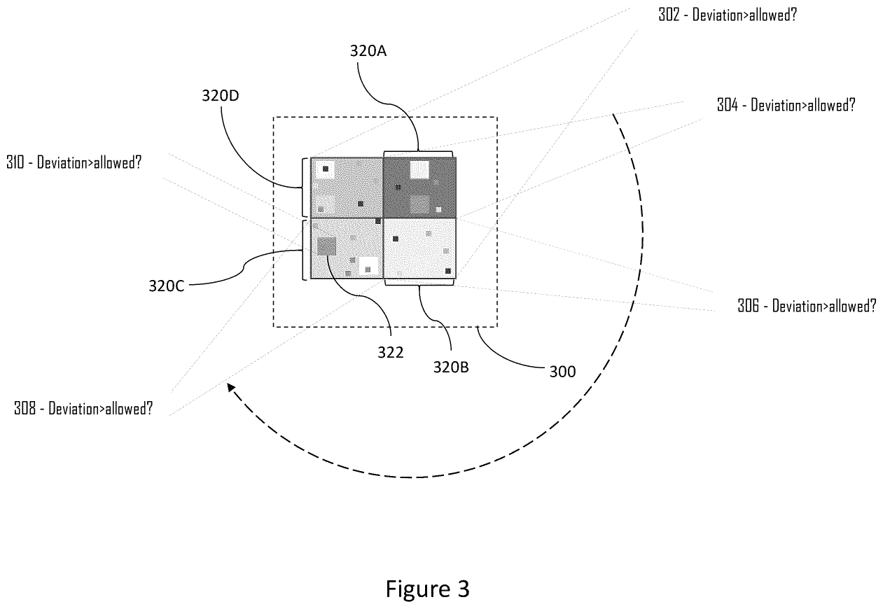

In an implementation, one or more coupling elasticity variables can be used as an elasticity trigger such that, if the one or more coupling elasticity variables achieves or exceeds a pre-defined condition or state, the self-adaptive solution will dynamically adjust the granularity or degree of coupling the digital twin 204 has with the physical artifact 200 that it represents. The elasticity trigger (also described subsequently in FIG. 3) therefore serves as a mechanism to detect when such adjustments are necessary and triggers the self-adaptive solution to initiate the corresponding actions. For example, when changes in the one or more coupling elasticity variables, such as the components of the digital twin 204, and/or when the digital twin's 204 (or its components) characteristics such as accuracy, precision, fidelity, simulation time or speed to solution exceed a pre-defined condition, the self-adaptive solution will dynamically adjust the granularity or degree of coupling the digital twin 204 has with the physical artifact 200 that it represents. In another example, coupling frequencies can be used as an elasticity trigger, such that the digital twin 204 (or its components) may only be allowed to operate within a pre-defined range of coupling frequencies with the physical artifact 200. In other implementations, the coupling frequencies can be associated with a pre-defined range of time constants or system dynamics within which the digital twin 204 (or its components) is allowed to operate.

FIG. 2D illustrates factors that influence how the self-adaptive solution described previously in FIGS. 1-2C dynamically and autonomously adjusts the granularity or degree of coupling between the digital twin 204 and the physical artifact 200. A central aggregator 218 may be utilized to derive insights, identify patterns, inform decision-making and trigger actions within the system 100 in order to select an appropriate granularity or degree of coupling between the digital twin 204 and the physical artifact 200. The central aggregator 218 may be a module that operates within the system 100.

A first factor that influences how the self-adaptive solution dynamically and autonomously adjusts the granularity or degree of coupling is the state of the digital twin 204, which is obtained and utilized by the central aggregator 218 in real-time. The state of the digital twin 204 mirrors the properties, behavior, and interactions of the physical artifact 200 that the digital twin 204 represents in real-time.

A second factor that the central aggregator 218 may utilize is user intuition, which may include manual input, oversight, or annotation that is performed by users. The user-interface (UI) 150 described previously in FIG. 1 may be utilized to provide users with access to the digital twin 204 and its components, and provide a visually appealing and user-friendly layout (e.g., depicting the digital twin 204 in a modular form), allowing users to navigate through different aspects of the digital twin 204. In addition the user-interface (UI) 150 may provide clear definitions of the digital twin's 204 components, including their input and output variables, as well as providing refinement parameters that allow users to adjust the resolution of the components representation in the digital twin 204. The user-interface (UI) 150 may therefore be used for effective management of the digital twin 204.

A third factor that the central aggregator 218 may utilize is policies that define preferences and restrictions under which the digital twin 204 should operate. These policies may include policies that express degrees of coupling between the digital twin 204 and the physical artifact 200 as a function of preferred/allowed false positives and/or negatives. For example, these may include decision support algorithms implemented in a policy domain specific language (DSL). In another example, these may include policies used to express, measure and report cost/benefit ratios to enable digital twin “what-if analysis”. These policies may also be organizational and/or government policies under which the digital twin 204 should operate. For example, these policies could be service level agreements (SLAs) that are mapped onto the domain specific language (DSL) of the digital twin 204. In another example, these policies could include composable policy layers that utilize a modular and flexible approach to defining and managing policies within the digital twin 204. These policies may include policies that set user interaction and automation preferences. For example, a policy engine may be utilized that defines or supports a domain-specific language (DSL) specifically designed to express policies relevant to a particular domain, industry, or application. In another example, these policies may define the extent to which user engagement versus automation is preferred during the operation of the digital twin 204.

The effectiveness of the autonomous adjustment of the granularity or degree of coupling between the digital twin 204 and the physical artifact 200 can be measured based on how well the digital twin 204 and the system 100 that the digital twin 204 operates on meets pre-defined service level agreements (SLAs), such as response times, availability, throughput, stability, or the like. In addition, the effectiveness can be measured based on overhead costs, return on investment measures, performance, power consumption, or the like.

In an implementation, the digital twin 204 may be a computational fluid dynamics (CFD) model in which fluid flow and heat transfer is simulated, and which involves creating a virtual representation of a complex system, such as a data center, airplane, ocean environment, or the like. Surrogate models, such as deep neural networks can then be trained from the high-fidelity data generated from the digital twin 204. These surrogate models have advantages in that, once trained, they can generate a solution in a shorter duration of time, making them useful for performing “what-if analysis” and optimization tasks for the digital twin 204. In addition, depending on the required accuracy, precision, and simulation speed (time to solution), a granularity of coupling between the complex system and the digital twin 204 can be adjusted as described in FIGS. 2A-2D. The resulting data generated from the digital twin 204 is then used to train the surrogate models to obtain the optimized solution.

In an implementation in which the complex system is an ocean, and the digital twin 204 is a CFD model, regions of recirculation and turbulence (eddies) within the ocean may be simulated using a fine-grained mesh in order to generate a solution. Due to the fine mesh of the digital twin 204, a longer duration of time may be needed to generate a solution that resolves the eddies. By autonomously adjusting the granularity or degree of coupling (e.g., by adjusting the degree of coupling depth between the complex system and the digital twin 204), a simulation time needed to generate a solution that resolves the eddies may be reduced since the surrogate model used to resolve the eddies may be trained from the high-fidelity data generated from the digital twin 204. In addition, the self-adaptive solution described above may be used to automate the identification of the location to apply the surrogate model, as well as a frequency of the surrogate model refresh (e.g., frequency of data exchange from the digital twin 204).

FIG. 3 illustrates an example implementation of the use of one or more elasticity triggers (described previously in FIG. 2C), which are a condition that initiates the self-adaptive solution (described previously in FIGS. 1-2D) to dynamically and autonomously adjust the granularity or degree of coupling a digital twin 300 has with the physical artifact 200 (described previously in FIGS. 2A-2D). The digital twin 300 may be similar to the digital twin 204 described previously in FIGS. 2A-2D, wherein the digital twin 300 may be a virtual representation of the physical artifact 200, and the digital twin 300 may operate on the system 100 that was described previously in FIG. 1.

During the example implementation, one or more coupling elasticity variables (described previously in FIG. 2C) can be used as an elasticity trigger such that, if the one or more coupling elasticity variables achieve or exceed a pre-defined condition or state, the self-adaptive solution may dynamically adjust the granularity or degree of coupling the digital twin 300 has with the physical artifact 200 that it represents. For example, the adjustment of the granularity or degree of coupling may include partitioning the digital twin 300 into a number of partitions. In addition, after the partitioning of the digital twin 300, the self-adaptive solution may try to make the digital twin 300 closely match or follow a reference input trajectory so that it meets specified performance criteria or objectives.

In a step 302 of the example implementation, if a deviation of one or more coupling elasticity variables relating to the digital twin 300 exceeds a pre-defined allowed condition or state, the self-adaptive solution may dynamically adjust the granularity or degree of coupling of the digital twin 300 by partitioning the digital twin 300 into partitions 320 (including partitions 320A, 320B, 320C, 320D) and sub-partitions 322 in order to represent a greater number of components and sub-components of the physical artifact 200. After the partitioning of the digital twin 300, the self-adaptive solution may proceed to examine the properties, behavior, and interactions of a first partition 320A of the partitions 320 of the digital twin 300.

In a step 304 of the example implementation, if during the step 302 a deviation of one or more coupling elasticity variables relating to the first partition 320A of the partitions 320 exceeds a pre-defined allowed condition or state, then the self-adaptive solution may proceed to examine the properties, behavior, and interactions of a second partition 320B of the partitions 320 of the digital twin 300.

In a step 306 of the example implementation, if a deviation of one or more coupling elasticity variables relating to the second partition 320B of the partitions 320 exceeds a pre-defined allowed condition or state, then the self-adaptive solution may proceed to examine the properties, behavior, and interactions of a third partition 320C of the partitions 320 of the digital twin 300.

In a step 308 of the example implementation, if a deviation of one or more coupling elasticity variables relating to the third partition 320C of the partitions 320 exceeds a pre-defined allowed condition or state, then the self-adaptive solution may proceed to examine the properties, behavior, and interactions of a sub-partition 322 within the third partition 320C.

In a step 310 of the example implementation, if a deviation of one or more coupling elasticity variables relating to the sub-partition 322 within the third partition 320C exceeds a pre-defined allowed condition or state, then the self-adaptive solution may proceed to examine the properties, behavior, and interactions of any other partition or sub-partition of the digital twin 300, or alternatively, the self-adaptive solution may initiate any action deemed appropriate, such as adjusting the granularity or degree of coupling the digital twin 300 has with the physical artifact 200.

The example implementation described above shows that, after the partitioning of the digital twin 300 is performed, the reference input trajectory of the digital twin 300 is shown to have a specific order. However, it should be recognized that the reference input trajectory of the digital twin 300 can follow any suitable order to meet specified performance criteria or objectives.

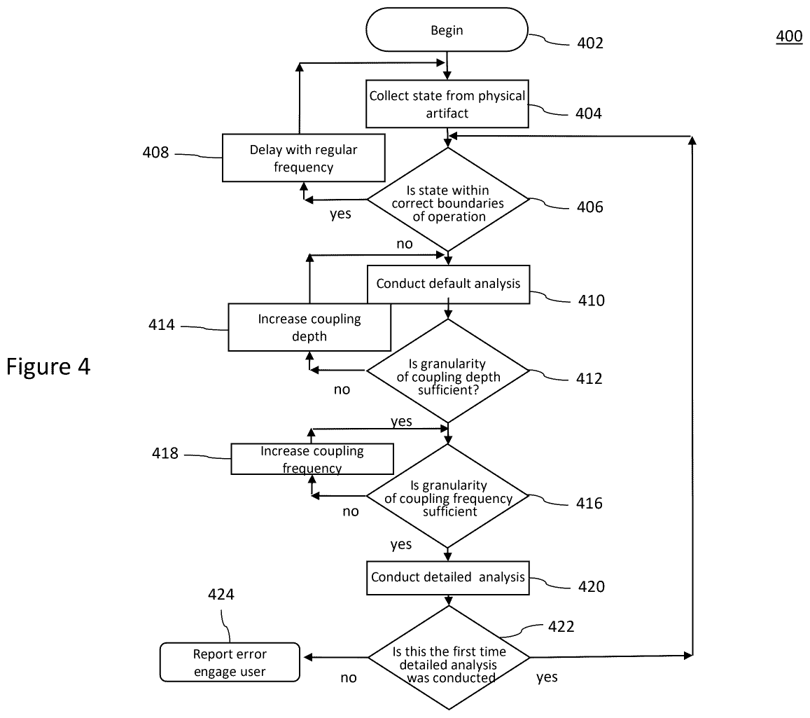

FIG. 4 illustrates a flowchart 400 for an adjustment process that is used to adjust the granularity or degree of coupling between the digital twin 204 and the physical artifact 200, according to some implementations. The dynamic and autonomous adjustment of the granularity or degree of coupling may be performed within the self-adaptive solution described previously in FIGS. 1-3.

Step 402 of the flowchart 400 marks the beginning of the adjustment process that is performed by the self-adaptive solution. In step 404, data of states (e.g., input data 110 described in FIG. 1) in real-time from the physical artifact 200 is collected at a first frequency by the system 100, wherein the states describe the performance of the physical artifact 200 in real-time. The data may be collected in real-time using data sensors and other data collection devices, or the like. The data is used to generate the digital twin 204 which represents a virtual representation of the physical artifact 200 in real-time.

In step 406 of the flowchart 400, an inspection of a state of the physical artifact 200 in real-time as represented by the digital twin 204 is performed to determine if the state is operating within correct boundaries of operation. A state operating or falling within boundaries of operation means it is within boundaries of operation that are desired or expected for the digital twin 204. If in step 406 the state is operating within correct boundaries of operation, then the data of the states continues to be collected (in real-time) by the system 100 from the physical artifact 200 at the first frequency as shown in step 408.

If in step 406 the state (in real-time) is determined to be not operating within the correct boundaries of operation, a default analysis is conducted as shown in step 410. The default analysis may include diagnostic processes to identify any immediate issues, risks, or opportunities for improvement within the digital twin 204.

In step 412 of the flowchart 400, a determination is made whether the granularity of coupling depth between the digital twin 204 and the physical artifact 200 is sufficient based on the detailed analysis conducted in step 410. For example, the granularity of coupling depth between the digital twin 204 and the physical artifact 200 may be deemed sufficient if an input value exceeds a pre-determined threshold value. In other implementations, the granularity of coupling depth between the digital twin 204 and the physical artifact 200 may be deemed sufficient if an input value lies between a pre-determined lower threshold value and upper threshold value. If it is determined in step 412 that the granularity of the coupling depth between the digital twin 204 and the physical artifact 200 is not sufficient, the self-adaptive solution adjusts the granularity of the coupling depth (e.g., as described previously in FIGS. 2A-2D) between the digital twin 204 and the physical artifact 200 as shown in step 414. For example, the self-adaptive solution may increase the granularity of coupling depth between the digital twin 204 and the physical artifact 200. The steps 410, 412, and 414 may be repeated cyclically until the granularity of the coupling depth between the digital twin 204 and the physical artifact 200 is deemed to be sufficient in step 412 of the flowchart 400.

If it is determined in step 412 that the granularity of coupling depth between the digital twin 204 and the physical artifact 200 is sufficient, then in step 416 of the flowchart 400, a determination is made whether the granularity of coupling frequency between the digital twin 204 and the physical artifact 200 is sufficient based on the detailed analysis conducted in step 410. If it is determined in step 416 that the granularity of the coupling frequency between the digital twin 204 and the physical artifact 200 is not sufficient, the self-adaptive solution will adjust the granularity of the coupling frequency (e.g., as described previously in FIGS. 2A-2D) between the digital twin 204 and the physical artifact 200 as shown in step 418. For example, the self-adaptive solution may increase the granularity of coupling frequency between the digital twin 204 and the physical artifact 200. The steps 416 and 418 may be repeated cyclically until the granularity of the coupling frequency between the digital twin 204 and the physical artifact 200 is deemed to be sufficient in step 416 of the flowchart 400. For example, the granularity of coupling frequency between the digital twin 204 and the physical artifact 200 may be deemed sufficient if an input value representing the frequency of interaction and state exchange between the digital twin 204 and the physical artifact 200 exceeds a pre-determined threshold value. If it is determined in step 416 that the granularity of coupling frequency between the digital twin 204 and the physical artifact 200 is sufficient, then in step 420 of the flowchart 400, a detailed analysis is conducted. This may involve performing a more detailed analysis of the data collected from the physical artifact 200, such as analyzing the data at a finer granularity or using more sophisticated analysis techniques.

After the step 420 is performed, a step 422 of the flowchart 400 is performed in which a determination is made whether the detailed analysis conducted in step 420 has been performed more than once. If it is determined in step 422 that the detailed analysis conducted in step 420 has not been performed more than once, then the step 406 of the flowchart 400 is repeated. After the step 406 is performed, the further steps of the flowchart 400 that follow the step 406 are performed as described above until it is determined in step 422 that the detailed analysis conducted in step 420 has been performed more than once. If it is determined in step 422 that the detailed analysis conducted in step 420 has been performed more than once, then step 424 is performed in which an error report is generated to notify a user that the state represented by the digital twin 204 in real-time is not within the correct boundaries of operation. For example, an error message may be displayed using the user-interface (UI) 150 (described previously in FIG. 1) requesting for operator or user intervention.

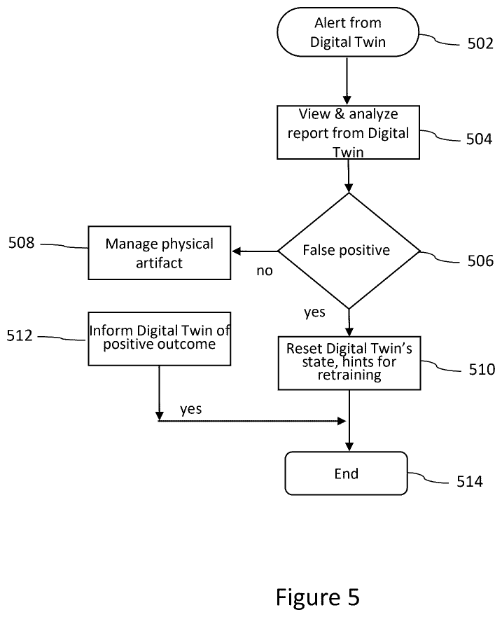

FIG. 5 illustrates a flowchart 500 for a process performed by a user in response to the error report generated in the step 424 of the flowchart 400 described previously in FIG. 4. In step 502, the error report along with an alert may be displayed using the user-interface (UI) 150 (described previously in FIG. 1), wherein the alert may request user intervention to manage the error.

In step 504, the user may view and analyze the error report using the user-interface (UI) 150. In step 506, the user will determine if the error in the error report is a false positive, where an error may be identified as present, even though it is actually absent. If it is determined in step 506 that the error in the error report is not a false positive, then the user will perform a step 508 in which the user manages the physical artifact 200 to resolve the error. If it is determined in step 506 that the error in the error report is a false positive, then the user may perform a step 510 that comprises resetting a state of the digital twin 204 to return it to a known state or an initial state. The step 510 may also comprise retraining the digital twin 204 by updating its model or parameters. Additionally, a step 512 may be performed in which the user provides input to inform the digital twin 204 of a positive outcome as a result of the step 508 that was performed to manage the physical artifact 200 and to resolve the error. Alternatively, in step 512, the user may provide input to inform the digital twin 204 of the action taken in step 508 that was performed to manage the physical artifact 200 and to resolve the error. Step 514 marks the ending of the user response process to the error report that was generated, wherein step 514 occurs when the steps 510 and 512 have been performed.

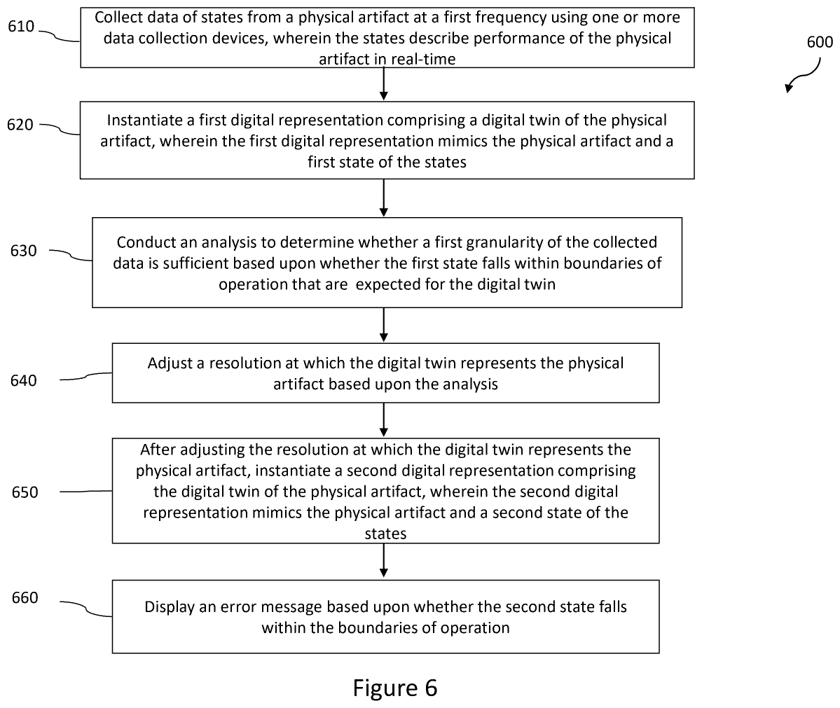

FIG. 6 illustrates an example method 600 for autonomously adjusting the granularity or degree of coupling between a digital twin (e.g., the digital twin 204 described previously in FIGS. 2A-2D) and a physical artifact (e.g., the physical artifact 200 described previously in FIGS. 2A-2D). The dynamic and autonomous adjustment of the granularity or degree of coupling may be performed by the self-adaptive solution described previously in FIGS. 1-3, according to certain implementations.

In step 610, data of states from a physical artifact are collected at a first frequency using one or more data collection devices, wherein the states describe performance of the physical artifact in real-time. For example, state data of states (e.g., input data 110 described in FIG. 1) from the physical artifact 200 in real-time is collected at a first frequency by the system 100, wherein the states describe the performance of the physical artifact 200 in real-time. The data may be collected using data sensors and other data collection devices, or the like.

In step 620, a first digital representation comprising a digital twin of the physical artifact is instantiated, wherein the first digital representation mimics the physical artifact and a first state of the states. For example, the input data 110 is used to generate the digital twin 204 which represents a virtual representation of a first state of the physical artifact 200.

In step 630, an analysis is conducted to determine whether a first granularity of the collected data is sufficient based upon whether the first state falls within boundaries of operation that are expected for the digital twin. For example, an inspection of a state of the physical artifact 200 in real-time as represented by the digital twin 204 may be performed to determine if the state is operating within boundaries of operation (described previously in FIG. 4) that are expected for the digital twin 204. If the state is determined to be not operating within the boundaries of operation, a default analysis is conducted, which may include diagnostic processes to identify any immediate issues, risks, or opportunities for improvement within the digital twin 204.

After the default analysis is conducted, a determination is made whether the granularity of coupling depth between the digital twin 204 and the physical artifact 200 is sufficient, based on the default analysis conducted (described previously in FIG. 4). In addition, after the default analysis is conducted, a determination is made whether the granularity of coupling frequency between the digital twin 204 and the physical artifact 200 is sufficient, based on the default analysis conducted (described previously in FIG. 4).

In step 640, a resolution at which the digital twin represents the physical artifact is adjusted based upon the analysis. For example, the granularity of the coupling depth between the digital twin 204 and the physical artifact 200 may be adjusted (e.g., as described previously in FIGS. 2A-2D) and/or the granularity of the coupling frequency between the digital twin 204 and the physical artifact 200 may be adjusted (e.g., as described previously in FIGS. 2A-2D).

In step 650, after adjusting the resolution at which the digital twin represents the physical artifact, a second digital representation comprising the digital twin of the physical artifact is instantiated, wherein the second digital representation mimics the physical artifact and a second state of the states. For example, the input data 110 is used to generate the digital twin 204 which represents a virtual representation of a second state of the physical artifact 200.

In step 660, an error message is displayed, the error message being based upon whether the second state falls within the boundaries of operation. For example, an error report may be generated to notify a user that the second state represented by the digital twin 204 (in real-time) is not within the boundaries of operation. In an implementation, an error message may be displayed using the user-interface (UI) 150 (described previously in FIG. 1), requesting operator or user intervention.

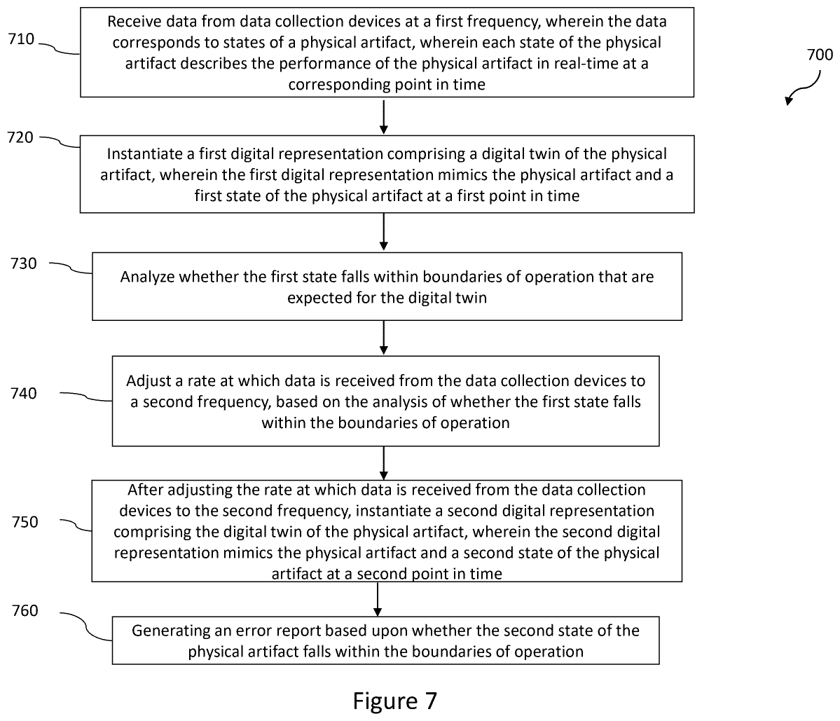

FIG. 7 illustrates an example method 700 for autonomously adjusting the granularity or degree of coupling between a digital twin (e.g., the digital twin 204 described previously in FIGS. 2A-2D) and a physical artifact (e.g., the physical artifact 200 described previously in FIGS. 2A-2D). The dynamic and autonomous adjustment of the granularity or degree of coupling may be performed by the self-adaptive solution described previously in FIGS. 1-3, according to certain implementations.

In step 710, data is received from data collection devices at a first frequency, wherein the data corresponds to states of a physical artifact, wherein each state of the physical artifact describes the performance of the physical artifact in real-time at a corresponding point in time. For example, state data of states (e.g., input data 110 described in FIG. 1) in real-time from the physical artifact 200 is collected at a first frequency by the system 100, wherein the states describe the performance of the physical artifact 200 in real-time. The data may be collected in real-time using data sensors and other data collection devices, or the like.

In step 720, a first digital representation comprising a digital twin of the physical artifact is instantiated, wherein the first digital representation mimics the physical artifact and a first state of the physical artifact at a first point in time. For example, the input data 110 is used to generate the digital twin 204 which represents a virtual representation of a first state of the physical artifact 200 in real-time.

In step 730, an analysis is performed of whether the first state falls within boundaries of operation that are expected for the digital twin. For example, an inspection of a state of the physical artifact 200 as represented by the digital twin 204 in real-time may be performed to determine if the state is operating within boundaries of operation (described previously in FIG. 4) that are expected for the digital twin 204. If the state is determined to be not operating within the boundaries of operation, a default analysis is conducted, which may include diagnostic processes to identify any immediate issues, risks, or opportunities for improvement within the digital twin 204. After the default analysis is conducted, a determination is made whether the granularity of coupling depth between the digital twin 204 and the physical artifact 200 is sufficient, based on the detailed analysis conducted (described previously in FIG. 4). In addition, after the default analysis is conducted, a determination is made whether the granularity of coupling frequency between the digital twin 204 and the physical artifact 200 is sufficient, based on the detailed analysis conducted (described previously in FIG. 4).

In step 740, a rate at which data is received from the data collection devices is adjusted to a second frequency, based on the analysis of whether the first state falls within the boundaries of operation. For example, the granularity of the coupling frequency between the digital twin 204 and the physical artifact 200 may be adjusted (e.g., as described previously in FIGS. 2A-2D).

In step 750, after adjusting the rate at which data is received from the data collection devices to the second frequency, a second digital representation comprising the digital twin of the physical artifact is instantiated, wherein the second digital representation mimics the physical artifact and a second state of the physical artifact at a second point in time. For example, the input data 110 is used to generate the digital twin 204 which represents a virtual representation of a second state of the physical artifact 200 in real-time.

In step 760, an error report is generated based upon whether the second state of the physical artifact falls within the boundaries of operation. For example, an error report may be generated to notify a user that the second state represented by the digital twin 204 in real-time is not within the boundaries of operation. In an implementation, an error message may be displayed using the user-interface (UI) 150 (described previously in FIG. 1) requesting for operator or user intervention.

The foregoing outlines features of several examples so that those skilled in the art may better understand the aspects of the present disclosure. Various modifications and combinations of the illustrative examples, as well as other examples, will be apparent to persons skilled in the art upon reference to the description. It is therefore intended that the appended claims encompass any such modifications.

What is claimed is:

1. A computer-implemented method comprising:
collecting data of states from a physical artifact at a first frequency using one or more data collection devices, wherein the states describe performance of the physical artifact in real-time;
instantiating a first digital representation comprising a digital twin of the physical artifact, wherein the first digital representation mimics the physical artifact and a first state of the states;
conducting an analysis to determine whether a first granularity of the collected data is sufficient based upon whether the first state falls within boundaries of operation that are expected for the digital twin;
adjusting a resolution at which the digital twin represents the physical artifact based upon the analysis to determine whether the first granularity of the collected data is sufficient;
after adjusting the resolution at which the digital twin represents the physical artifact, instantiating a second digital representation comprising the digital twin of the physical artifact, wherein the second digital representation mimics the physical artifact and a second state of the states; and
displaying an error message based upon whether the second state falls within the boundaries of operation.

2. The method of claim 1, further comprising:
conducting an analysis to determine whether a granularity of a coupling frequency between the physical artifact and the digital twin is sufficient based upon whether the first state falls within the boundaries of operation.

3. The method of claim 2, further comprising:
adjusting the coupling frequency between the physical artifact and the digital twin based upon the analysis to determine whether the granularity of coupling frequency between the physical artifact and the digital twin is sufficient, wherein after adjusting the coupling frequency, data of the states from the physical artifact is collected at a second frequency using the one or more data collection devices.

4. The method of claim 3, wherein the second frequency is different from the first frequency.

5. The method of claim 4, wherein the second frequency is greater than the first frequency.

6. The method of claim 1, wherein displaying the error message comprises:
generating an error report; and
presenting the error report on a graphical user-interface (GUI).

7. The method of claim 1, further comprising:
after adjusting the resolution at which the digital twin represents the physical artifact, conducting a further analysis to determine whether a second granularity of the collected data is sufficient based upon whether the second state falls within the boundaries of operation.

8. The method of claim 7, further comprising:
based upon the further analysis to determine whether the second granularity of the collected data is sufficient, adjusting the resolution at which the digital twin represents the physical artifact.

9. A computer-implemented method comprising:
receiving data from data collection devices at a first frequency, wherein the data corresponds to states of a physical artifact, wherein each state of the physical artifact describes performance of the physical artifact in real-time at a corresponding point in time;
instantiating a first digital representation comprising a digital twin of the physical artifact, wherein the first digital representation mimics the physical artifact and a first state of the physical artifact at a first point in time;
analyzing whether the first state falls within boundaries of operation that are expected for the digital twin;
adjusting a rate at which data is received from the data collection devices to a second frequency based on the analysis of whether the first state falls within the boundaries of operation;
after adjusting the rate at which data is received from the data collection devices to the second frequency, instantiating a second digital representation comprising the digital twin of the physical artifact, wherein the second digital representation mimics the physical artifact and a second state of the physical artifact at a second point in time; and
generating an error report based upon whether the second state of the physical artifact falls within the boundaries of operation.

10. The method of claim 9, wherein the second frequency is greater than the first frequency.

11. The method of claim 9, further comprising:
adjusting a resolution at which the digital twin represents the physical artifact based on the analysis of whether the first state falls within the boundaries of operation.

12. The method of claim 11, wherein adjusting the resolution comprises increasing the resolution at which the digital twin represents the physical artifact to include a representation of a greater number of components and sub-components of the physical artifact.

13. The method of claim 11, further comprising:
analyzing whether the second state falls within the boundaries of operation based on whether the analysis of whether the first state falls within the boundaries of operation is the only analysis that has been performed on a state of the states of the physical artifact.

14. The method of claim 9, further comprising displaying the error report in a visual format on a graphical user-interface (GUI).

15. A system comprising:
one or more processors; and
one or more non-transitory computer-readable storage media storing programming for execution by the one or more processors, the programming comprising instructions to:
collect data of states from a physical artifact at a first frequency using one or more data collection devices, wherein the states describe performance of the physical artifact in real-time;
instantiate a first digital representation comprising a digital twin of the physical artifact, wherein the first digital representation mimics the physical artifact and a first state of the states;
conduct an analysis to determine whether a coupling variable between the digital twin and the physical artifact exceeds a pre-defined condition;
adjust a resolution at which the digital twin represents the physical artifact based upon whether the coupling variable exceeds the pre-defined condition;
instantiate a second digital representation comprising the digital twin of the physical artifact, wherein the second digital representation mimics the physical artifact and a second state of the states; and
after instantiating the second digital representation, generate an error report based upon whether the coupling variable between the digital twin and the physical artifact exceeds the pre-defined condition.

16. The system of claim 15, wherein the programming further comprises instructions to adjust a coupling frequency between the physical artifact and the digital twin based upon whether the coupling variable exceeds the pre-defined condition, wherein after adjusting the coupling frequency, data of the states from the physical artifact is collected at a second frequency using the one or more data collection devices.

17. The system of claim 16, wherein the second frequency is greater than the first frequency.

18. The system of claim 15, wherein the programming further comprises instructions to present the digital twin to a user with a graphical user-interface (GUI).

19. The system of claim 18, wherein the programming further comprises instructions to present the error report to the user.

20. The system of claim 15, wherein adjusting the resolution at which the digital twin represents the physical artifact comprises increasing the resolution at which the digital twin represents the physical artifact to include a representation of a greater number of components and sub-components of the physical artifact.
